(19) United States
(12) Patent Application Publication
(10) Pub. No.: US 2012/0309125 A1
(43) Pub. Date: Dec. 6, 2012

(54) BUFFER LAYER DEPOSITION METHODS FOR GROUP IBIIIAVIA THIN FILM SOLAR CELLS

(75) Inventors: Serdar Aksu, San Jose, CA (US); Sarah Lastella, Mountain View, CA (US); Mustafa Pinarbasi, Morgan Hill, CA (US)

(73) Assignee: SoloPower, Inc., San Jose, CA (US)

(21) Appl. No.: 13/154,273

(22) Filed: Jun. 6, 2011

(51) Int. Cl. H01L 31/18

(52) U.S. Cl. 438/57; 257/E31.119

(57) ABSTRACT

The present invention provides methods for forming a buffer layer for Group IBIIIAVIA solar cells. The buffer layer is formed using chemical bath deposition and the layer is formed in steps. A first buffer layer is formed on the absorber and the first buffer layer is then treated using etching, oxidizing, annealing or some combination thereof. Subsequently a second buffer layer is then positioned on the treated surface. Additional buffer layers can be added following treatment of the previously deposited layer.

### BACKGROUND

1. Field of the Invention

The present invention relates to methods and apparatus for preparing thin films for solar cells, and more specifically to buffer layer deposition methods for solar cells or photovoltaic devices using Group IBIIIAVIA compound semiconductor films.

2. Description of the Related Art

Solar cells are photovoltaic (PV) devices that convert sunlight directly into electrical energy. Solar cells can be based on crystalline silicon or thin films of various semiconductor materials that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells, including copper indium gallium diselenide (CIGS) based solar cells, have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂ is formed on the conductive Mo film. The substrate 11 and the contact layer 12 form a base layer 13. Although there are other methods, Cu(In,Ga)(S,Se)₂ type compound thin films are typically formed by a two-stage process where the components (components being Cu, In, Ga, Se and S) of the Cu(In,Ga)(S,Se)₂ material are first deposited onto the substrate or a contact layer formed on the substrate as an absorber precursor, and are then reacted with S and/or Se in a high temperature annealing process.

After the absorber film 14 is formed, a transparent layer 15 including a buffer film or layer, such as CdS, and a transparent conductive layer, such as an undoped-ZnO/doped-ZnO stack or an undoped-ZnO/In—Sn—O (ITO) stack, can be formed on the absorber film. In manufacturing the solar cell, the buffer layer is first deposited on the Group IBIIIAVIA absorber film 14 to form an active junction. Then the transparent conductive layer is deposited over the buffer layer to provide the needed lateral conductivity. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate, such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

Contrary to CIGS and amorphous silicon cells, which are fabricated on conductive substrates such as aluminum or stainless steel foils, standard silicon solar cells are not deposited or formed on a protective sheet. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell. Circuits may then be packaged in protective packages to form modules. Each module typically includes a plurality of strings of solar cells which are electrically connected to one another.

In a thin film solar cell employing a Group IBIIIAVIA compound absorber, the cell efficiency is a strong function of the molar ratio of IB/IIIA. If there are more than one Group IIIA materials in the composition, the relative amounts or molar ratios of these IIIA elements also affect the properties. For a Cu(In,Ga)(S,Se)₂ absorber layer, for example, the efficiency of the device is a function of the molar ratio of Cu/(In +Ga). Furthermore, some of the important parameters of the cell, such as its open circuit voltage, short circuit current and fill factor, vary with the molar ratio of the IIIA elements, i.e. the Ga/(Ga+In) molar ratio. In general, for good device performance the Cu/(In +Ga) molar ratio is kept at around or below 1.0. On the other hand, as the Ga/(Ga+In) molar ratio increases, the optical bandgap of the absorber layer increases and therefore the open circuit voltage of the solar cell increases while the short circuit current typically may decrease. It is important for a thin film deposition process to have the capability of controlling both the molar ratio of IB/IIIA, and the molar ratios of the Group IIIA components in the composition.

Various buffer layers with various chemical compositions have been evaluated in solar cell structures. CdS, ZnS, Zn—S-OH, Zn—S-O-OH, ZnO, Zn—Mg—O, Cd—Zn—S, ZnSe, In—Se, In—Ga—Se, In—S, In—Ga—S, In—O-OH, In—S-O, In—S-OH, etc. are some of the buffer layer materials that have been reported in the literature. Buffer layers for Group IBIIIAVIA devices such as CIGS(S) solar cells are typically 5-200 nm thick and may be deposited by various techniques such as evaporation, sputtering, atomic layer deposition (ALD), electrodeposition and chemical bath deposition (CBD), etc.

Chemical bath deposition (CBD) is the most commonly used method for the formation of buffer layers on CIGS(S) absorber films. The prior art techniques involve preparation of a chemical bath comprising the chemical ingredients of the buffer layer to be formed. The temperature of the bath is raised to a typical range of 50-90° C. and the surface of the CIGS(S) film is exposed to the heated bath. Alternately, the substrate containing the CIGS(S) film may be heated and then dipped into the chemical bath kept at a lower temperature. A thin buffer layer grows onto the CIGS(S) film as a result of homogeneous chemical reactions initiating upon application of heat to the bath and/or to the substrate carrying the CIGS(S) film.

An exemplary CBD process for the growth of a cadmium sulfide (CdS) buffer layer employs a chemical bath comprising cadmium (Cd) species (from a Cd salt source such as Cd-chloride, Cd-sulfate, Cd-acetate, etc.), sulfur (S) species (from a S source such as thiourea) and a complexing agent (such as ammonia, triethanolamine (TEA), diethanolamine (DEA), ethylene diamine tetra-acetic acid (EDTA), etc) that regulates the reaction rate between the Cd and S species. Once the temperature of such a bath is increased to the 50-90° C. range, the reaction between the Cd and S species initiates homogeneously everywhere in the solution. As a result, a CdS layer forms on all surfaces wetted by the heated solution and CdS particles form homogeneously within the solution. The reaction rate between Cd and S species is a function of temperature. The rate increases as the temperature is increased and it decreases as the temperature is reduced. The deposition is usually completed in a single step, and thus the last deposited part of the CdS film often includes unwanted large CdS particulates, which cause roughness and lead to a compromise in the junction formation with the subsequently formed transparent layers of the cell structure which can have intrinsic ZnO and transparent conductive oxides such as Al-doped ZnO or indium tin oxide.

While the use of CBD CdS junction formation has resulted in high conversion efficiencies for CIGS solar cells, its use in high volume manufacturing is problematic owing to such non-uniformity problems often encountered in CdS films which are often accompanied by unwanted porosity and large CdS grains. Therefore, there is still a need to improve CdS deposition techniques in producing CIGS solar cell devices.

### SUMMARY OF THE INVENTION

The present invention provides methods for depositing CdS buffer layers on Group IBIIAVIA thin films.

In one aspect, the invention includes a multistep CdS deposition process including at least one of the following between the deposition steps: thermal annealing in vacuum or inert atmosphere, partial oxidation of the CdS surface by exposing it to air or O₂-rich atmosphere, or by annealing in air or O₂ environment, and partial chemical etching of the CdS surface.

In one aspect, the aforementioned needs are met by one embodiment of the present invention which comprises a method of a multi-step chemical bath depositing a buffer layer including cadmium-sulfide (CdS) over a Group IBIIIAVIA absorber layer formed on a conductive base in manufacturing a solar cell. In this embodiment, the method comprises depositing a first buffer film layer, having a first exposed surface, from a first buffer deposition solution at a first solution temperature onto the absorber layer, the first buffer film including CdS. In this embodiment, the method further comprises applying a first treatment process to treat the first buffer film, the first treatment process transforms the first exposed surface into a first treated surface of the first buffer film. In this embodiment, the method further comprises depositing a second buffer film layer that includes CdS, having a second exposed surface, from a second buffer deposition solution at a second solution temperature onto the first treated surface of the first buffer film, the second buffer film layer including CdS.

The aforementioned needs are also satisfied by another embodiment of the present invention which comprises a method of forming a Group IBIIIAVIA thin film solar cell. The method in this embodiment comprises forming an absorber layer on a substrate in a first process station and forming a first buffer layer on an exposed surface of the absorber layer by moving the absorber layer on the substrate through a deposition solution in a chemical deposition tank where a CdS layer is deposited. The method further comprises treating the first buffer layer to improve the interface between the first buffer layer and the second buffer layer and to diffuse Cd atoms into the absorber layer. The method further comprises forming a second buffer layer on the outer surface of the first buffer layer by moving the absorber layer on the substrate through a deposition solution in a chemical deposition tank where a CdS layer is deposited and forming a transparent layer so as to overlie the first and second buffer layers.

### BRIEF DESCRIPTION OF THE DRAWINGS

FIG. 1 is a schematic side view of a thin film solar cell including a Group IBIIIAVIA compound absorber layer;

FIG. 2 is a schematic side view of a first buffer film formed deposited onto a CIGS absorber formed on a base;

FIGS. 3A and 3B are schematic detail views of buffer layers formed using embodiments of a multi-step buffer layer forming process;

FIGS. 3C, 4A, 4B, 4C and 5 are a schematic detail views of a buffer layer formed using another embodiment of a multi-step buffer layer forming process; and

FIG. 6 is a schematic view of a thin film solar cell structure including a buffer layer formed according to the embodiments of FIGS. 3-5.

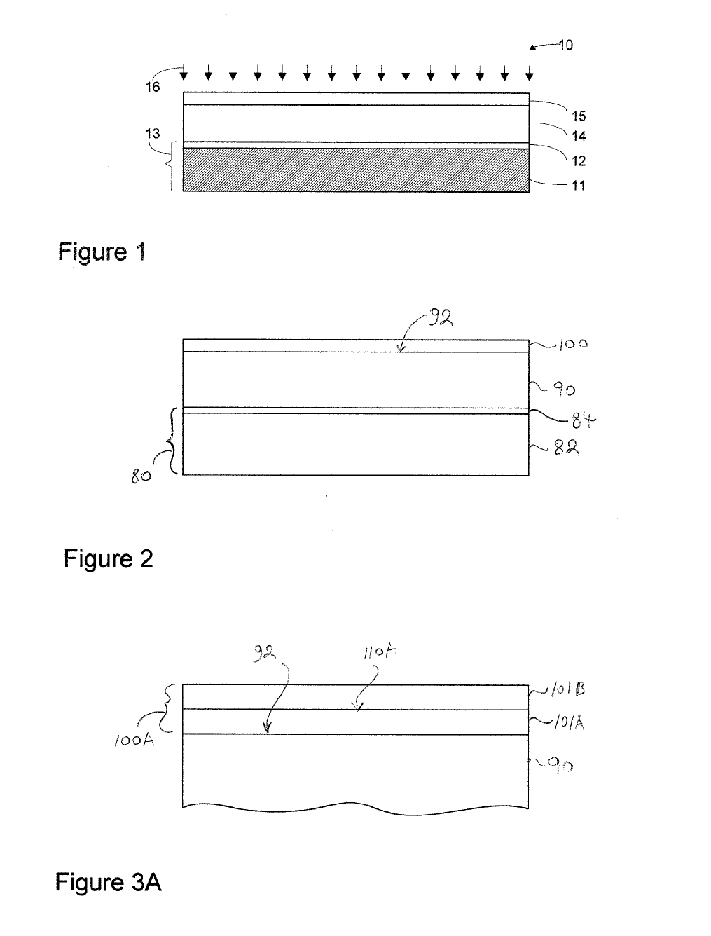

### DETAILED DESCRIPTION

The present invention provides a method for a multi-step chemical bath deposition (CBD) of a buffer layer to manufacture photovoltaic devices, such as solar cells, detectors and the like. In one embodiment, a buffer layer including cadmium-sulfide (CdS) may be deposited over a Group IBIIIAVIA absorber layer, such as a CIGS layer, formed on a conductive base. In this multi-step deposition process, initially, a first buffer film or a first film portion of the CdS buffer layer is deposited onto the CIGS absorber layer. The first buffer film is subsequently treated by a treatment process including at least one of anneal, etching and oxidation. Within the context of this specification, anneal treatment includes a thermal process performed in vacuum or inert atmosphere at a predetermined temperature range. Oxidation treatment may partially or fully oxidize the deposited CdS film and may be performed at room temperature in an oxygen or air atmosphere. Alternatively, CdS film may be thermally oxidized by annealing in an air or oxygen atmosphere. When used, the etching treatment partially etches the deposited CdS film surfaces or oxidized CdS surfaces with a liquid etchant. After treating the first buffer film, a second buffer film is deposited onto the first buffer film and the second buffer film is subsequently treated. Multiple buffer films may be similarly deposited and treated to form the final buffer layer.

As will be explained below, a treatment step of the process aims to prepare the surface of the deposited film for the next buffer film deposition, which improves the quality of both the exposed surface of the deposited buffer film or films and the junction that is formed between the CIGS absorber and the final CdS buffer layer formed by such treated buffer films. A smooth junction with fewer defects between the CIGS and CdS layers results in higher solar cell efficiencies.

It has been experimentally observed that the deposition of CdS on CIGS is a process depending on many factors dealing with adsorbed oxygen, sulfur and cadmium ion concentrations, temperature, pH, complexing agent concentrations (such as ammonia), CIGS surface stoichiometry, and the like. As mentioned above, during the deposition process, CdS particles or crystals may grow both in the deposition solution and on the exposed CIGS surface. Precipitation of CdS in solution may be limited by reducing the Cd-ion concentration in solution and ultimately reducing the growth rate of CdS on the CIGS surface. With this controlled slow deposition technique, the CdS may be deposited by the favored ion-by-ion growth mechanism that may produce relatively compact, dense CdS films with more uniform particle size at the beginning of the deposition. However, as the same deposition process is extended over a period of time, studies have also shown that the CdS film, which begins as a compact film, may continue growing into a porous, loosely packed, non-uniform structure. Thus, a controlled reduction of the deposition period may produce a compact, dense CdS film with a limited thickness. But a film with such limited thickness may be under the required thickness of the buffer layer. In the following embodiments, multiple thin CdS films with controlled thickness are deposited to form a uniform, dense buffer layer with required thickness that protects the underlying CIGS layer during the subsequent top contact processing steps using, for example, sputter deposition.

Accordingly, in one embodiment, a method of depositing thick, small particle, compact, dense CdS films on CIGS layers by incorporation of a treatment process including, for example, an oxidation and/or etching process between at least two separate CdS deposition steps is provided. The oxidation step(s) allows Cu atoms to diffuse into the bulk of the CIGS crystal from the CIGS surface and Cd atoms from the CdS to diffuse into these newly formed Cu vacancies in the CIGS crystal surface. Ultimately, solar cell efficiencies are improved with the diffusion of Cd into these Cu vacancies near the surface of the CIGS layer. For example, oxidation of the CdS film in air up to temperatures of 200° C. appears to induce Cu to diffuse from the CIGS surface down into the bulk CIGS. The resulting Cu vacancies at the CIGS/CdS interface are then filled by Cd atoms from the CdS layer. This combined diffusion has been shown to improve the CIGS/CdS interface by creating a graded interface rather than an abrupt band bending between the two layers. Further, an etching step after oxidation of the first CdS layer can be included to remove the oxide formation at the surface of the CdS film which may improve the interface between the first and second CdS layers.

FIG. 2 shows an initial step of the deposition process wherein a buffer layer 100 including CdS is formed on a top surface 92 of a CIGS absorber layer 90 using the multi step process of this embodiment. The top surface 92 forms the physical junction between the absorber layer 90 and the buffer layer 100 that will be formed with the multi-step deposition process. The absorber layer 90 is formed over a base 80 including a substrate 82 and a contact layer 84. The CIGS absorber layer 90 may be formed using a deposition process to deposit an absorber precursor including Cu, In, Ga and Se on the base 80 and subsequently thermally reacting this precursor to form the CIGS absorber layer 90 on the base. The precursor may be formed by an electroplating process. The base 80 may be a continuous flexible base or web so that each layer of the solar cell, i.e., absorber, buffer and transparent layers, may be continuously formed on the same base using a roll-to-roll manufacturing process. The substrate 82 may be a conductive substrate such as stainless steel, and the contact layer 84 may include molybdenum (Mo) and other conductive materials with ohmic contact and diffusion barrier characteristics.

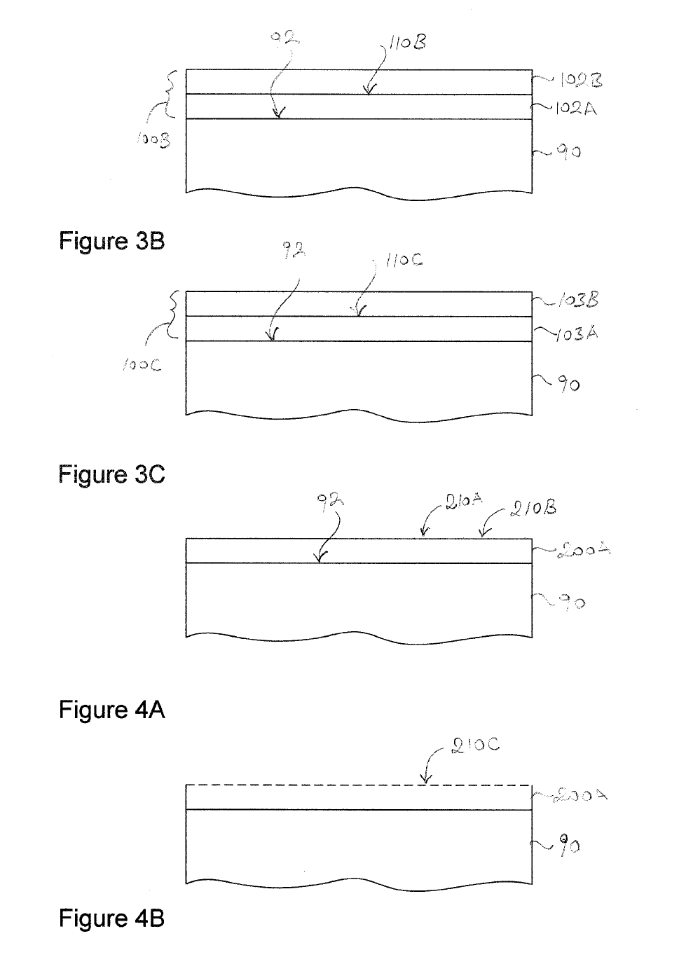

FIGS. 3A-3C show various multi-step chemical bath deposition embodiments using exemplary treatment process steps. For example, in one embodiment, a buffer layer 100A may be formed by first depositing a first buffer film 101A from a first deposition solution, annealing the first buffer film 101 A with the absorber layer 90 in a treatment step and, in a second deposition step, depositing a second buffer film 101B from a second deposition solution onto a top surface 110A or exposed top surface of the first buffer film 101 A. The anneal process may be carried out in vacuum or inert atmosphere, such as N₂ or Ar atmosphere, at a temperature range of 30° C. to 250° C. for about 1 second to 30 minutes.

In another embodiment, a buffer layer 100B may be formed by first depositing a first buffer film 102A from a deposition solution, etching a top surface 110B or exposed surface of the first buffer film 102A in a treatment step and, in a second deposition step, depositing a second buffer film 102B from a second deposition solution onto the top surface 110B, which is partially etched, of the first buffer film 102A. In one implementation, the etching process may be carried out using a liquid etchant or etching solution. A wide range of solvents may be used for the preparation of the etching solutions, including water, DI water, and organic liquids as well as mixtures of water and organic liquids. Use of organic liquids or their mixtures with water as the solvent may provide benefits such as reducing the surface tension of the etching solution for improved wetting. Sources of organic solvents include different alcohols, such as ethanol, methanol, and iso-propyl alcohol as well as other common organic solvents, i.e., acetonitrile and propylene carbonate. Etching solutions of this embodiment may be either acidic or alkaline. Acidic etching solutions may be prepared using inorganic and organic acids such as sulfuric acid, hydrochloric acid, nitric acid, acetic acid, sulfamic acid, citric acid, tartaric acid, acetic acid, boric acid, oxalic acid, phosphoric acid. The acid molarity concentration may range between 0.001 and 1 moles per liter, and more preferably between 0.01 and 0.1 moles per liter. The pH of the acidic etching solutions may be between 0 and 5, but preferably between 1 and 3. Alkaline etching solutions of the present invention may be prepared at a higher pH regime with the use of organic etchant species such as maleic acid, oxalic acid, ethylenediamine, tartaric acid, gluconic acid, citric acid, and glycine. The concentration of etchant species in the etching solution may range between 0.001 and 1 moles per liter and more preferably 0.01 and 0.1 moles per liter. The pH range for the etching solution may be between 7.0 and 13.5, preferably between 8 and 12.5. The pH of the etching solution may be adjusted with the addition of sodium hydroxide (NaOH) and potassium hydroxide (KOH). Alkaline buffers may also be added to the etching solution to maintain a fixed pH range. In addition to the organic etchants above, ammonia may also be used, but not preferred because of ammonia's high volatility and pungent smell. Etching solutions may also employ chemical oxidants such as hydrogen peroxide, or derivatives to increase the etch rate. Although both alkaline and acidic chemistries may be used successfully in the present invention for oxide removal, alkaline etching solutions may be more preferable because they provide more controllable etch rates while the main advantage of acidic etchants is their simplicity. The etching process removes at least a monolayer of oxidized material or approximately 5 Å from the top surface 110B.

In yet another embodiment, a buffer layer 100C may be formed by first depositing a first buffer film 103A from a first deposition solution, oxidizing a top surface 110C or exposed surface of the first buffer film 103A in a treatment step and, in a second deposition step, depositing a second buffer film 103B from a second deposition solution onto the top surface 110C, which is oxidized, of the first buffer film 102A. The oxidation process may be carried out in air or O₂-rich atmosphere with O₂ partial pressure in the range of 0.25-0.50 Atm. Alternatively, the oxidation process may be carried out thermally by exposing the first buffer layer 103A to a temperature range of 30 to 250° C. for about 1 second to 30 minutes in air or O₂ environment. The oxidation depth may be in the range of 5 to 1500 Å from the top surface 110C. In the above embodiments, the number of CdS buffer films may be greater than two and before and/or after any deposition and treatment process step, a cleaning and drying step may be applied to remove residues and to clean the surfaces. Before each CdS deposition step the related treatment process is applied to the previously deposited layer or the exposed surface of the previously deposited layer. An average thickness for the first and second buffer films may be in the range of 10 to 1500 Å. The first and second deposition solutions may or may not have the same composition. Similarly the deposition solution temperatures may be the same or different.

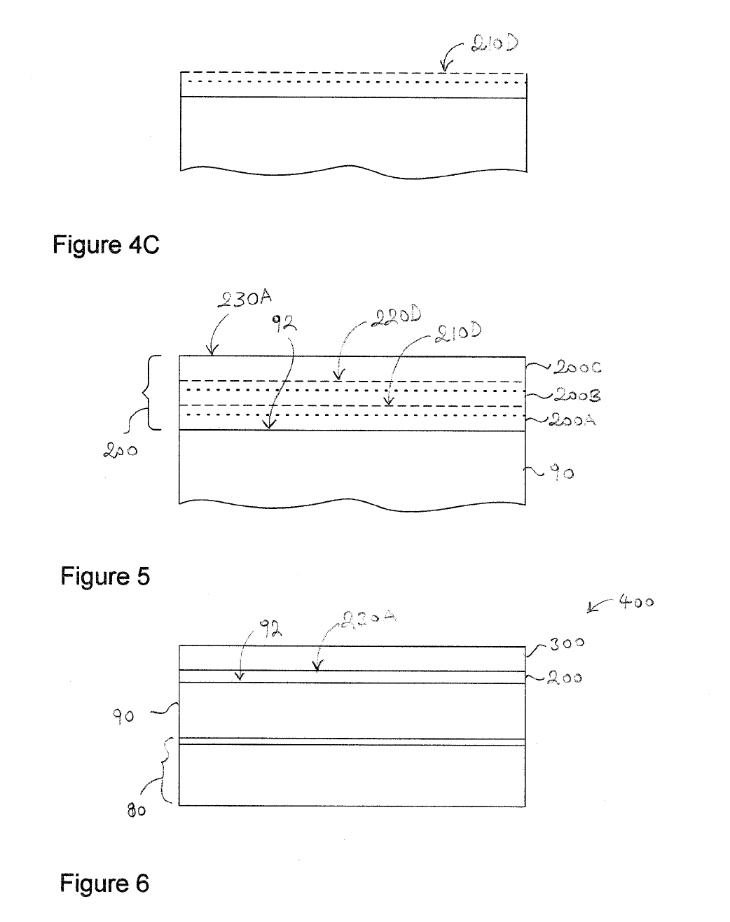

FIGS. 4A-5 show an embodiment of the multi-step deposition process using a combination of the above described treatment processes to build a CdS buffer layer 200 on the CIGS absorber layer 90 shown in FIG. 5.

Accordingly as shown in FIG. 4A, initially, a first buffer film 200A having a top surface 210A is deposited on the top surface 92 of the absorber layer 90 from a first deposition solution as in the previous embodiments. After depositing the first buffer film 200A, in a first treatment process step, the buffer film 200A and the absorber film 90 are annealed in vacuum or an inert atmosphere which results in an annealed top surface 210B. As described above, the anneal process may be carried out in vacuum or inert atmosphere, such as N₂ or Ar atmosphere, at a temperature range of 30° C. to 250° C. for about 1 second to 30 minutes.

As shown in FIG. 4B, after the first treatment process step, in a second treatment process step, the annealed top surface 210B is etched using an etching solution to form an etched top surface 210C of the first buffer film 200A. As described above, the etching process may be carried out using either an acidic or alkaline etching solution, preferably in the alkaline etching solution due to the more controllable etch rates. The etching process removes at least a 5 Å thick material layer from the surface.

As shown in FIG. 4C, in a third treatment step, the etched surface 210C is oxidized and transformed into an oxidized surface 210D. As described above, the oxidation process may be carried out in air or O₂—rich atmosphere with O₂ partial pressure in the range of 0.25-0.50 Atm. Alternatively, the oxidation process may be carried out thermally by exposing the etched top surface 210C to a temperature range of 30 to 250° C. for about 1 second to 30 minutes in air or O₂ environment. The oxidation depth may be in the range of 5 to 1500 Å from an oxidized top surface 220D. After any deposition and treatment step the first buffer film may be rinsed and dried.

As shown in FIG. 5, once the treatment process of the first buffer film is completed, a second buffer film 200B is deposited from a second deposition solution and treated using the same treatment process sequence to form an oxidized top surface 220D of the second buffer film 200B. Subsequently, a third buffer film 200C from a third deposition solution may be deposited onto the oxidized top surface 220D of the second buffer film 200B. In this embodiment the three step CdS deposition forms the buffer layer 200 on the absorber layer 90. As shown in FIG. 6, a transparent layer 300 deposited onto the buffer layer 200 to complete the solar cell structure 400. As a reference, the final thickness of all combined CdS layers should be within the range of 500 to 1500 Å for a 1.5 um thick CIGS device. The first, second and third deposition solutions may have the same composition and the solution temperature. Alternatively they may have different compositions and temperatures. For example, the first solution may have a first composition and first temperature; the second solution may have a second composition and second temperature; and, the third solution may have a third composition and a third temperature. Accordingly, the first, second and third compositions may be the same or different compositions. The first, second and third temperatures may be the same or different temperatures. In the above embodiments a preferred CdS bath composition used for each layer is 0.0005 M to 0.01 M Cd, 0.001 M to 0.50 M thiourea, and 0.05 to 3.0 M ammonia.

### Example 1

CdS films can be deposited on a CIGS surface using a 1.5 mM Cd²⁺, 0.07 M thiourea, and 2 M ammonia solution between 60 and 70° C. The first CdS film can be limited to be approximately 200 to 300 Å. This CdS film can be then annealed at 150° C. in air for 5 minutes. After cooling the sample for about 10 minutes, another CdS film can be deposited to form the CdS buffer layer reaching a total thickness of approximately 800 to 900 Å. In experiments employing the approach used in this example the cell efficiency was increased by about up to 8% compared to experiments employing conventional single step CdS layer deposition producing the similar thickness.

### Example 2

A first CdS film can be deposited on a CIGS surface with a 1.5 mM Cd²⁺, 0.07 M thiourea, and 2 M ammonia solution between 60 and 70° C. to achieve a thickness between 900 and 1100 Å. The CdS layer can be subjected to air oxidation between 1 minute and 24 hours. After the oxidation treatment, the first CdS film can be etched for 10 seconds to 1 minute in an etching solution, and the second CdS film can be deposited on the etched surface of the first CdS film. The second layer can be approximately 300 to 500 Å thick. In experiments employing the approach used in this example the cell efficiency was increased by about up to 13% compared to experiments employing conventional single step CdS deposition producing the similar thickness.

Accordingly, a first CdS film can be deposited at a different temperature, at a different CdS solution make-up, and consequently at a different growth rate and morphology than the second film CdS layer.

### Example 3

A 100 to 200 Å CdS film can be chemically grown on a CIGS surface with a 0.5 mM Cd²⁺, 0.02 M thiourea, and 2 M ammonia solution between 30 and 50° C. After deposition, the first CdS film can be oxidized in air between 1 minute and 24 hrs. This first film is deposited purposely at a much slower deposition rate by using a lower Cd and thiourea concentration as well as maintaining the bath at a relatively lower temperature. The slow deposition of the first film allows one to control the thickness of this film accurately. A second CdS film (about 500 Å thick) can be deposited with a 2 mM Cd²⁺, 0.1 M thiourea, and 2 M ammonia solution between 60 and 70° C. Here the elevated temperature and Cd concentration allows the second film to grow faster on the first film thereby increasing the CdS thickness on the CIGS to protect the CIGS from further processing steps. The second film can be oxidized in air from 1 minute to 24 hrs to help diffuse the Cd down below the CdS/CIGS interface, and then etched with 0.001 M hydrochloric acid. A third CdS layer can also be deposited on this etched CdS stack with a 1.5 mM Cd²⁺, 0.07 M thiourea, and 2 M ammonia solution between 60 and 70° C. with a thickness of about 300 to 500 Å. The deposition rate in this solution composition is slightly lower than that of the second step to accurately control the final thickness of the final CdS layer comprising the stack of CdS films.

Customization of deposition process parameters such as T, CdS bath concentration etc. for each particular step will allow optimization of each CdS film individually in a multi-step process, yielding to a final resultant CdS buffer layer tailored for all the desired morphological and compositional needs to improve CIGS cell efficiencies.

Cd to S ratio is often non-stoichiometric in the CdS films. In addition to CdS, there is some Cd oxide and hydroxide mixed into CdS film during the growth. Although not well-understood, compositional grading of Cd, S, O in the CdS films affect the cell efficiency. The multi-step depositions combined with treatment steps as described above allow this compositional grading to be tailored with the change of process conditions of each layer.

Although the present invention is described with respect to certain embodiments described above, modifications, changes and alterations thereto will be apparent to those skilled in the art. Hence, the scope of the present invention should not be limited to the foregoing description, but should be defined by the appended claims.

We claim:

1. A method of multi-step chemical bath depositing a buffer layer including cadmium-sulfide (CdS) over a Group IBIIIAVIA absorber layer formed on a conductive base in manufacturing a solar cell, the method comprising:
depositing a first buffer film layer, having a first exposed surface, from a first buffer deposition solution at a first solution temperature onto the absorber layer, the first buffer film including CdS;
applying a first treatment process to treat the first buffer film, the first treatment process transforms the first exposed surface into a first treated surface of the first buffer film; and
depositing a second buffer film layer that includes CdS, having a second exposed surface, from a second buffer deposition solution at a second solution temperature onto the first treated surface of the first buffer film, the second buffer film layer including CdS.

2. The method of claim 1 wherein the first treatment process includes at least one of anneal, oxidation and etching.

3. The method of claim 1 further including the step of applying a cleaning and rinsing process before and after applying the first treatment.

4. The method of claim 1 further including the step of applying a second treatment process to treat the second buffer film layer, the second treatment process transforms the second exposed surface into a second treated surface of the first buffer film, wherein the second treatment process includes at least one of anneal, oxidation and etching.

5. The method of claim 4 further including the step of depositing a third buffer film layer from a third buffer deposition solution onto the second treated top surface of the second buffer film layer, the third buffer film layer including CdS.

6. The method of claim 1, wherein the first treatment process includes anneal performed in vacuum or inert atmosphere at a temperature range of 30 to 250° C. for a period of 1 second to 30 minutes, and wherein the first treated surface is an annealed surface.

7. The method of claim 1, wherein the first treatment process includes oxidation performed in air or O₂—rich atmosphere with O₂ partial pressure in the range of 0.25-0.50 Atm, and wherein the first treated surface is an oxidized surface.

8. The method of claim 1, wherein the first treatment process includes oxidation performed in air or oxygen (O₂) atmosphere at a temperature range of 30 to 250° C. for a period of 1 second to 30 minutes, wherein the first treated surface is an oxidized surface.

9. The method of claim 1, wherein the first treatment process includes etching performed using a liquid etchant and, wherein the first treated surface is an etched surface.

10. The method of claim 1, wherein the thickness of the first buffer film layer is in the range of 5-1500 Angstroms, and the thickness of the second buffer film layer is in the range of 5-1500 Angstroms.

11. The method of claim 1, wherein the deposition solution used to deposit the first and second film layers includes, 0.0005 M to 0.01 M Cd, 0.001 M to 0.50 M thiourea, and 0.05 to 3.0 M ammonia.

12. The method of claim 1, wherein the Group IBIIIAVIA absorber layer is a CIGS absorber layer.

13. The method of claim 1, wherein the first treatment process includes the steps of:
annealing the absorber and the first buffer film layer in a vacuum or inert atmosphere at a predetermined temperature range, wherein the anneal transforms the exposed surface to an annealed surface;
etching the annealed surface using a liquid etchant to form an etched surface; and
oxidizing the etched surface in air or oxygen (O₂) atmosphere to form an oxidized surface.

14. The method of claim 13, wherein the step of anneal is performed at a temperature range of 30 to 250° C. for a period of 1 second to 30 minutes.

15. The method of claim 13, wherein the step of etching uses a liquid etchant solution with a solvent selected from one of water, organic liquids, and a mixture of water and organic liquids.

16. The method of claim 15 wherein the organic liquid is selected from ethanol, methanol, and iso-propyl alcohol, acetonitrile and propylene carbonate.

17. The method of claim 15 wherein the liquid etchant is prepared in an acidic pH range between 0 and 5, can comprise inorganic and organic acids including sulfuric acid, hydrochloric acid, nitric acid, acetic acid, sulfamic acid, citric acid, tartaric acid, acetic acid, boric acid, oxalic acid, phosphoric acid in the molarity concentration can range between 0.001 and 1 moles per liter.

18. The method of claim 15 wherein the liquid etchant is prepared in an alkaline pH range between 7.0 and 13.5 and comprises organic etchant species including maleic acid, oxalic acid, ethylenediamine, tartaric acid, gluconic acid, citric acid, and glycine in the molarity concentration can range between 0.001 and 1 moles per liter.

19. The method of claim 18 wherein the alkaline pH is adjusted with addition of sodium hydroxide and potassium hydroxide and with the use of alkaline pH buffers.

20. The method of claim 15 wherein the liquid etchant solution further employs chemical oxidants including hydrogen peroxide, or derivatives to increase the etch rate.

21. The method of claim 13, wherein the step of oxidation includes a thermal oxidation conducted at a temperature range of 30 to 250° C. for a period of 1 second to 30 minutes.

22. The method of claim 13 further including the step of applying a cleaning and rinsing process after applying the steps of anneal, etching and oxidation.

23. The method of claim 13 further including the step of applying a second treatment process to treat the second buffer film layer, the second treatment process transforms the second exposed surface into a second treated surface of the first buffer film layer, wherein the second treatment process includes at least one of anneal, oxidation and etching.

24. The method of claim 18 further including the step of depositing a third buffer film from the buffer deposition solution onto the second treated top surface of the second buffer film.

25. The method of claim 1 wherein the first buffer deposition solution composition and the second buffer deposition solution composition are the same.

26. The method of claim 21 wherein the first solution temperature and the second solution temperature are the same.

27. A method of forming a Group IBIIIAVIA thin film solar cell comprising:
forming an absorber layer on a substrate in a first process station;
forming a first buffer layer on an exposed surface of the absorber layer by moving the absorber layer on the substrate through a deposition solution in a chemical deposition tank where a CdS layer is deposited;
treating the first buffer layer to improve the interface between the first buffer layer and the second buffer layer and to diffuse Cd atoms into the absorber layer;
forming a second buffer layer on the outer surface of the first buffer layer by moving the absorber layer on the substrate through a deposition solution in a chemical deposition tank where a CdS layer is deposited; and
forming a transparent layer so as to overlie the first and second buffer layers.

28. The method of claim 27, wherein treating the first buffer layer comprises at least one of oxidizing, etching or annealing the first buffer layer.

29. The method of claim 28 further including the step of applying a cleaning and rinsing process before and after the treating the first buffer layer.

30. The method of claim 28 further comprising treating the second buffer layer.

31. The method of claim 28, wherein treating the first buffer layer comprises annealing the first buffer layer in vacuum or inert atmosphere at a temperature range of 30 to 250° C. for a period of 1 s to 30 minutes, and wherein the outer surface of the first buffer layer is an annealed surface.

32. The method of claim 28, wherein treating the first buffer layer comprises oxidizing the first buffer layer in an air or O₂—rich atmosphere with O₂ partial pressure in the range of 0.25-0.50 Atm, and wherein the outer layer is an oxidized surface

33. The method of claim 28, wherein treating the first buffer layer comprises etching the first buffer layer using a liquid etchant and, wherein the outer surface of the first buffer layer is an etched surface.

34. The method of claim 27, wherein the thickness of the first buffer layer is in the range of 5-1500 Angstroms, and the thickness of the second buffer layer is in the range of 5-1500 Angstroms.

35. The method of claim 27, wherein the Group IBIIIAVIA absorber layer is a CIGS absorber layer.

36. The method of claim 27, wherein treating the first buffer layer includes the steps of:
annealing the absorber and the first buffer layer in vacuum or inert atmosphere at a predetermined temperature range, wherein the anneal transforms the exposed surface to an annealed surface;
etching the annealed surface using a liquid etchant to form an etched surface; and oxidizing the etched surface in an air or oxygen (O₂) atmosphere to form an oxidized surface.

37. The method of claim 27, wherein the first and second buffer layers are formed by positioning the first and second buffer layers in chemical deposition tanks not necessarily containing either the same material or the same processing temperature.

38. The method of claim 27, wherein the buffer layer is deposited in two or more layers to achieve a dense, compact buffer film.
